(19) United States
(12) Patent Application Publication
(10) Pub. No.: US 2016/0380047 A1
(43) Pub. Date: Dec. 29, 2016

(54) SEMICONDUCTOR DEVICE

(71) Applicant: KABUSHIKI KAISHA TOSHIBA, Tokyo (JP)

(72) Inventors: Takuma HARA, Kanazawa Ishikawa (JP); Yusuke KAWAGUCHI, Miura Kanagawa (JP)

(21) Appl. No.: 15/057,042

(22) Filed: Feb. 29, 2016

(30) Foreign Application Priority Data
Jun. 29, 2015 (JP) 2015-129374

(51) Int. Cl. H01L 29/06; H01L 29/423; H01L 29/417; H01L 23/535; H01L 29/78

(52) U.S. Cl. CPC H01L 29/0615; H01L 23/535; H01L 29/7849; H01L 29/41775; H01L 29/42356

(57) ABSTRACT

A semiconductor device includes a first electrode, a first semiconductor layer of a first conductivity type located on the first electrode, a second semiconductor layer of a second conductivity type located on the first semiconductor layer, a third semiconductor layer of the first conductivity type located on a portion of the second semiconductor layer, a second electrode located in the first semiconductor layer, the second semiconductor layer and the third semiconductor layer, the second electrode extending along and around an outer edge of the first semiconductor layer, and spaced from the second semiconductor layer by an insulating film, a wiring located on the third semiconductor layer and connected to the second electrode, and a third electrode connected to the second semiconductor layer and the third semiconductor layer.

### CROSS-REFERENCE TO RELATED APPLICATION

This application is based upon and claims the benefit of priority from Japanese Patent Application No. 2015-129374, filed Jun. 29, 2015, the entire contents of which are incorporated herein by reference.

### FIELD

Embodiments of the present invention relate to a semiconductor device.

### BACKGROUND

A vertical type semiconductor device having a trench gate in the semiconductor layer has been developed in the past. Such a semiconductor device includes, for example, MOSFET (Metal-Oxide-Semiconductor Field-Effect Transistor), DTMOS (Dynamic Threshold MOS), and IGBT (insulated gate bipolar transistor), and is mainly used for power control. In such a semiconductor device, it is required to reduce the resistance value in an ON state (on-resistance) as much as possible.

### DESCRIPTION OF THE DRAWINGS

FIG. 1 is a plan view of a semiconductor device according to a first embodiment;

FIG. 2 is a sectional view taken along the line A-A′ of FIG. 1;

FIG. 3 is a sectional view taken along the line B-B′ of FIG. 1;

FIG. 4 is a plan view of a semiconductor device according to a comparative example;

FIG. 5 is a plan view of a semiconductor device according to a second embodiment; and

FIG. 6 is a plan view of a semiconductor device according to a third embodiment.

### DETAILED DESCRIPTION

Embodiments provide a semiconductor device having a low on-resistance.

In general, according to one embodiment a semiconductor device includes a first electrode, a first semiconductor layer of a first conductivity type located on the first electrode, a second semiconductor layer of a second conductivity type located on the first semiconductor layer, a third semiconductor layer of the first conductivity type located on a portion of the second semiconductor layer, a second electrode located in the first semiconductor layer, the second semiconductor layer and the third semiconductor layer, the second electrode extending along and around an outer edge of the first semiconductor layer, and spaced from the second semiconductor layer by an insulating film, a wiring located on the third semiconductor layer and connected to the second electrode, and a third electrode connected to the second semiconductor layer and the third semiconductor layer.

### First Embodiment

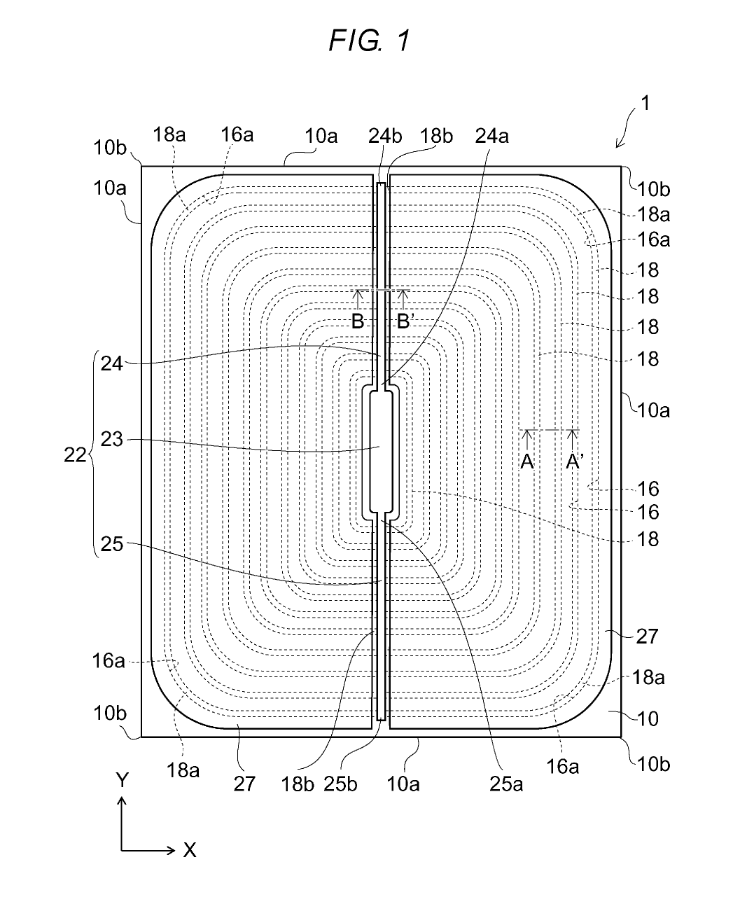

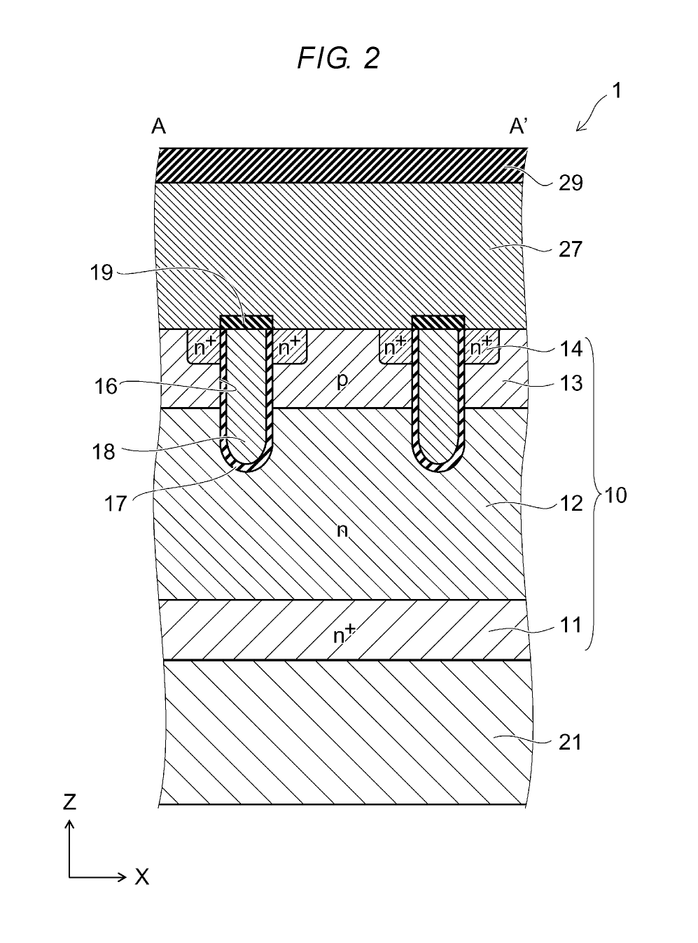

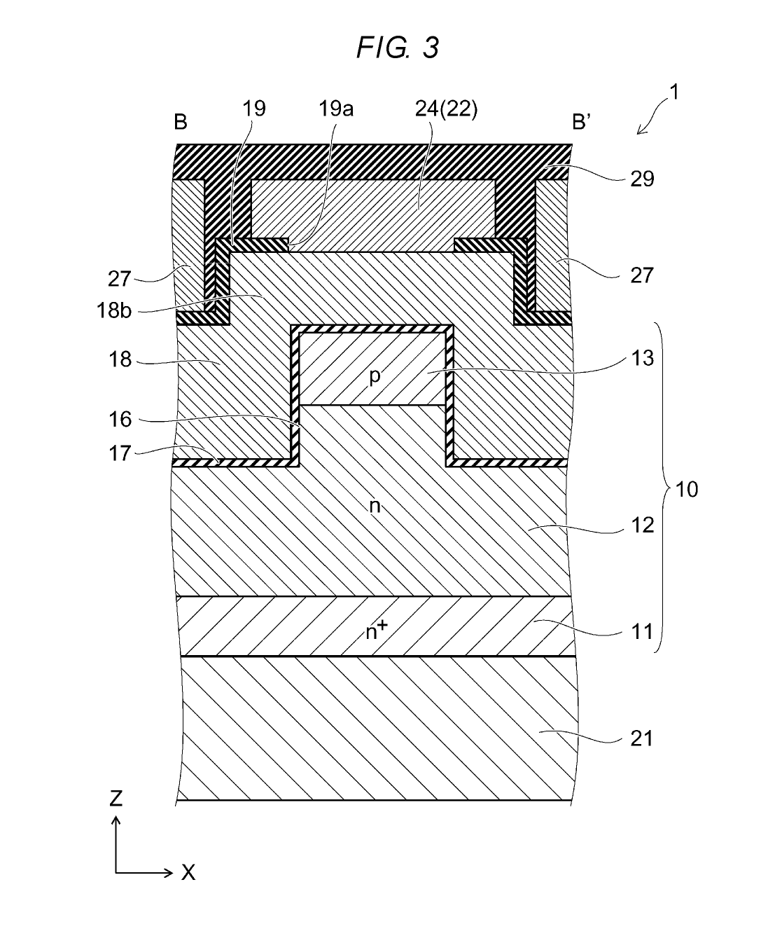

First, a first embodiment will be described. FIG. 1 is a plan view showing a semiconductor device according to the embodiment. FIG. 2 is a sectional view taken along the line A-A′ of FIG. 1. FIG. 3 is a sectional view taken along the line B-B′ of FIG. 1. Note that each figure is schematic, and the dimensions and ratios between components, the number of components, as well as the aspect ratio of each component do not necessarily correspond to those of an actual product. For example, in each figure, the number of trench gate electrodes 18, described later, is smaller than those in an actual product, and the size thereof is larger than those in an actual product. The semiconductor device according to the embodiment is, for example, a vertical type MOSFET for power control.

As shown in FIGS. 1 to 3, in the semiconductor device 1 according to the embodiment, a silicon chip 10 having a rectangular plate shape is provided. For example, the silicon chip 10 is made of single-crystal silicon. For convenience of explanation, an XYZ orthogonal coordinate system is used in this specification. Hereinafter, the lateral direction of the silicon chip 10 is defined as the “X-direction”, the longitudinal direction of the silicon chip 10 is defined as the “Y-direction”, and the thickness direction of the silicon chip 10 is defined as the “Z-direction.”

A drain layer 11 having an n⁺-type conductivity is provided in the lower portion of the silicon chip 10. A drift layer 12 having an n-type conductivity is provided on the drain layer 11. A base layer 13 having a p-type conductivity is provided on the drift layer 12. A source layer 14 having an n⁺-type conductivity is provided on a part of the base layer 13. The carrier concentration of the drain layer 11 and of the source layer 14 are higher than the carrier concentration of the drift layer 12.

A plurality of trenches 16 are formed on the silicon chip 10 extending into the upper surface side of the silicon chip 10. The trenches 16 penetrate through the source layer 14 and the base layer 13, and extend into the upper portion of the drift layer 12. Further, when viewed from the Z-direction, the trenches 16 are formed in a loop shape. A plurality of trenches 16 are provided and spaced from one another, and are arranged at equal spacing and concentrically from one another, for example. Incidentally, although a corner portion 10b of the silicon chip 10 has a substantially sharp L-shape, in the vicinity of the corner portion 10b, a corner portion 16a of each of the trenches 16 is curved gently in an X-Y plane direction.

For example, a gate insulating film 17 made of silicon oxide is provided on the inner surface of the trench 16. For example, the trench gate electrode 18 made of polysilicon is provided on the gate insulating film 17 inside the trench 16. The trench gate electrode 18 is insulated from the silicon chip 10 by the gate insulating film 17. Thus, the trench gate electrode 18 is opposed to the upper portion of the drift layer 12, the base layer 13 and the source layer 14 via the gate insulating film 17. In other words, the source layer 14 is arranged in a loop shape on either side of the trench 16 along the trench 16.

The corner portion 18a of the trench gate electrode 18 located in the vicinity of the corner portion 10b of the silicon chip 10 is gently curved in an X-Y plane direction along the corner portion 16a of the trench 16. Therefore, when viewed from the Z-direction, the curvature of the corner portion 18a of the trench gate electrode 18 is smaller, i.e., less sharp, than the curvature of the corner portion 10b of the silicon chip 10. Therefore, when viewed from the upper side, that is, from the Z-direction, the maximum curvature of the trench gate electrode 18 is smaller than the maximum curvature of the outer edge 10a of the silicon chip 10. For example, an insulating film 19 made of silicon oxide is provided on the trench gate electrode 18.

A drain electrode 21 is provided below the silicon chip 10. The drain electrode 21 is made of metal such as aluminum, and is in contact with the entire lower surface of the silicon chip 10, for example.

Agate wiring 22 is provided on the silicon chip 10. The gate wiring 22 is made of metal such as aluminum. Overall, the gate wiring 22 is in a substantially straight line linear shape extending in the Y-direction. More specifically, in the gate wiring 22, a pad portion 23 has a substantially rectangular shape when viewed from the Z-direction, and wiring portions 24 and 25 extending therefrom in the Y-direction from opposite sides of the pad 23 are integrally provided. The pad portion 23 is a portion to which a wire may be wire-bonded, for example, and in which a control potential is input from the external power supply.

When viewed from the Z-direction, the pad portion 23 is arranged in a region including the center of the loops of the trench gate electrodes 18. The wiring portion 24 extends in the Y-direction, one end portion 24a of which is connected to the pad portion 23, and the other end portion 24b of which is terminated in the vicinity of the end portion (side) of the silicon chip 10 in the Y-direction, and intersects with the outermost trench gate electrode 18. Similarly, the wiring portion 25 also extends in the Y-direction, one end portion 25a of which is connected to the pad portion 23, and the other end portion 25b of which is terminated in the vicinity of the end portion (side) of the silicon chip 10 in the Y-direction, and intersects with the outermost trench gate electrode 18.

In this manner, when viewed from the Z-direction, each trench gate electrode 18 is arranged in a loop shape having rounded corners, and the gate wiring 22 is arranged in a substantially linear shape extending in the Y-direction, thus, each trench gate electrode 18 intersects with the gate wiring 22 at two places . That is, each trench gate electrode 18 intersects with the wiring portion 24 at one portion thereof and intersects with the wiring portion 25 at another portion thereof.

As shown in FIG. 3, in a portion where each trench gate electrode 18 intersects with the wiring portion 24, the trench gate electrode 18 is raised relative to the silicon chip 10. That is, in the intersection portion, the bottom of the trench 16 does not reach the drift layer 12 and the trench gate electrode 18 is located on the base layer 13. In the other words, in the intersection portion, the gate insulating film 17 and the trench gate 18 are lifted onto the base layer 13. An opening 19a is formed in the insulating film 19 on a portion 18b of the trench gate electrode 18 arranged on the silicon chip 10, and the wiring portion 24 of the gate wiring 22 is arranged thereon. Thus, the portion 18b of the trench gate electrode 18 is connected to the wiring portion 24 of the gate wiring 22 through the opening 19a in the insulating film 19. Also in a portion where the trench gate electrode 18 intersects with the wiring portion 25, the trench gate electrode 18 is connected to the wiring portion 25 through the opening 19a in the insulating film 19. Thus, each trench gate electrode 18 is connected to the gate wiring 22 at two places.

As shown in FIG. 1, a source electrode 27 is provided in a region where the gate wiring 22 is not provided on the silicon chip 10. The source electrode 27 is made of metal such as aluminum, and is connected to the base layer 13 and the source layer 14. On the other hand, the source electrode 27 is insulated from the trench gate electrode 18 by the insulating film 19. Then, a passivation film 29 made of, for example, silicon oxide is provided to cover the silicon chip 10, the gate wiring 22 and the source electrode 27. Note that, for convenience of explanation, the passivation film 29 is not shown in FIG. 1. Openings (not shown) are formed in a portion corresponding to a region directly above the pad portion 23 in the passivation film 29, and a region directly above a wire-bonded portion of the source electrode 27.

Next, the operation of the semiconductor device 1 according to the embodiment will be described. As shown in FIG. 2, in the semiconductor device 1, a relatively negative potential, for example, a ground potential is applied to the source electrode 27, and a relatively positive potential is applied to the drain electrode 21. Then, reverse bias voltage is applied to the interface between the n-type drift layer 12 and the p-type base layer 13, and a depletion layer expands starting from the interface therebetween. Therefore, no current flows between the drain electrode 21 and the source electrode 27, and the semiconductor device 1 is turned off.

In this state, when a positive potential greater than a threshold voltage is applied to the gate wiring 22, the potential is conveyed to the trench gate electrodes 18, an inversion layer is formed in the base layer 13 in the vicinity of the gate insulating film 17, and a current flows between the drain electrode 21 and the source electrode 27. Such a MOSFET operation turns on the semiconductor device 1.

At this time, a MOS region for passing a current is generated between the drain electrode 21 and the source electrode 27. On the other hand, as shown in FIG. 3, no MOSFET is formed immediately below the gate wiring 22, thus, a current does not flow there. Therefore, no MOS region is generated immediately below the gate wiring 22, thus, resulting in a dead space with respect to energization.

Next, the effects of the embodiment will be described. In the embodiment, since, when viewed from the Z-direction, the trench gate electrodes 18 are arranged in a loop shape, and the gate wiring 22 is arranged in a substantially linear shape, the gate electrode 22 can be connected to all of the trench gate electrodes 18 while reducing the area of the gate electrode 22. By reducing the area of the gate electrode 22, the area of the source electrode 27 can be correspondingly increased, and thus it is possible to substantially increase the MOS region for passing a current in the silicon chip 10. As a result, it is possible to reduce the on-resistance of the semiconductor device 1.

Further, gently curving the corner portions 18a of each of the trench gate electrodes 18 can suppress concentration of the electric field on the corner portion 18a, thus, it is possible to increase the voltage withstand properties of the semiconductor device 1.

Further, in the embodiment, the portion 18b of the trench gate electrode 18 connected to the gate wiring 22 is arranged on the upper side of the silicon chip 10. Thus, since the gate electrode 22 is arranged on the portion 18b, the gate electrode 22 is spaced from the silicon chip 10, and is insulated from the silicon chip 10 by the gate insulating film 17 and the trench gate electrode 18. As a result, no special configuration is required for insulating the gate electrode 22 from the silicon chip 10.

### Comparative Example

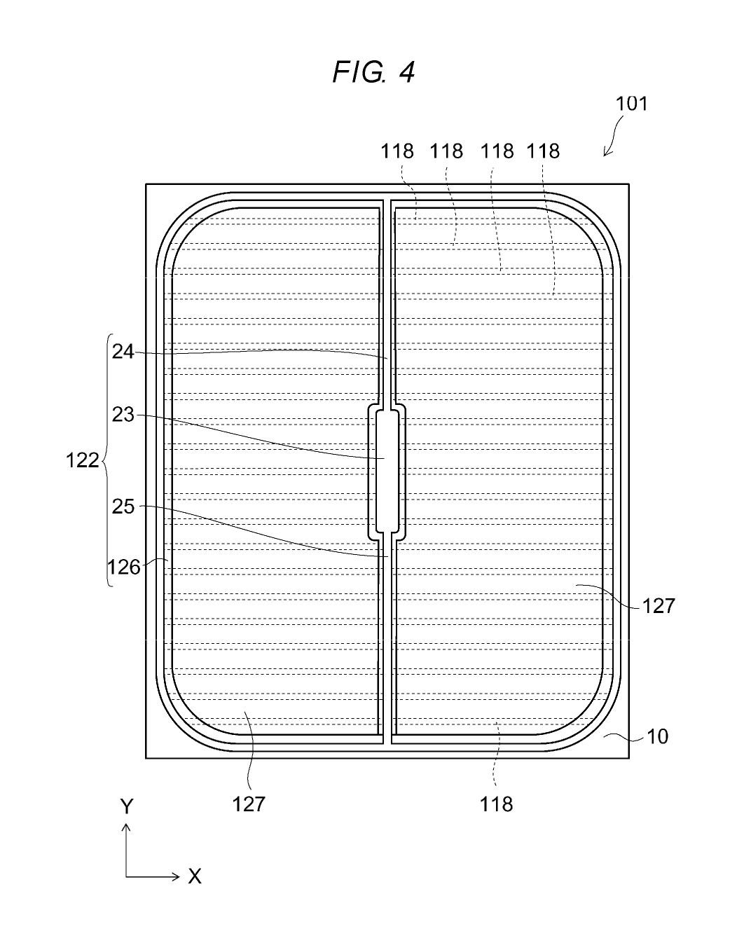

Next, a comparative example will be described. FIG. 4 is a plan view showing a semiconductor device according to the comparative example. As shown in FIG. 4, in a semiconductor device 101 according to the comparative example, each trench gate electrode 118 is arranged in a straight-line linear shape extending in the X-direction, not in a loop shape. Further, in addition to the pad portion 23 and the wiring portions 24 and 25, an outer peripheral portion 126 is provided in the gate wiring 122. The outer peripheral portion 126 is arranged in a loop shape along the outer edge 10a of the semiconductor chip 10. Moreover, the outer peripheral portion 126 is connected to the end portions of the wiring portions 24 and 25.

As compared to the semiconductor device 1 according to the first embodiment (see FIG. 1), in the semiconductor device 101 according to the comparative example, the outer peripheral portion 126 is provided, therefore, the area of the gate wiring 122 is correspondingly larger when viewed from the Z direction. For this reason, the area of the source electrode 127 is smaller. Therefore, as compared to the first embodiment, the area of the MOS region is smaller, and the on-resistance is higher.

In addition, in the semiconductor device 101 according to the comparative example, since the trench gate electrode 118 is arranged in a linear shape, the electric field tends to concentrate on the end portions thereof. Therefore, the voltage withstand properties of the semiconductor device 101 are lower than that of the semiconductor device 1.

### Second Embodiment

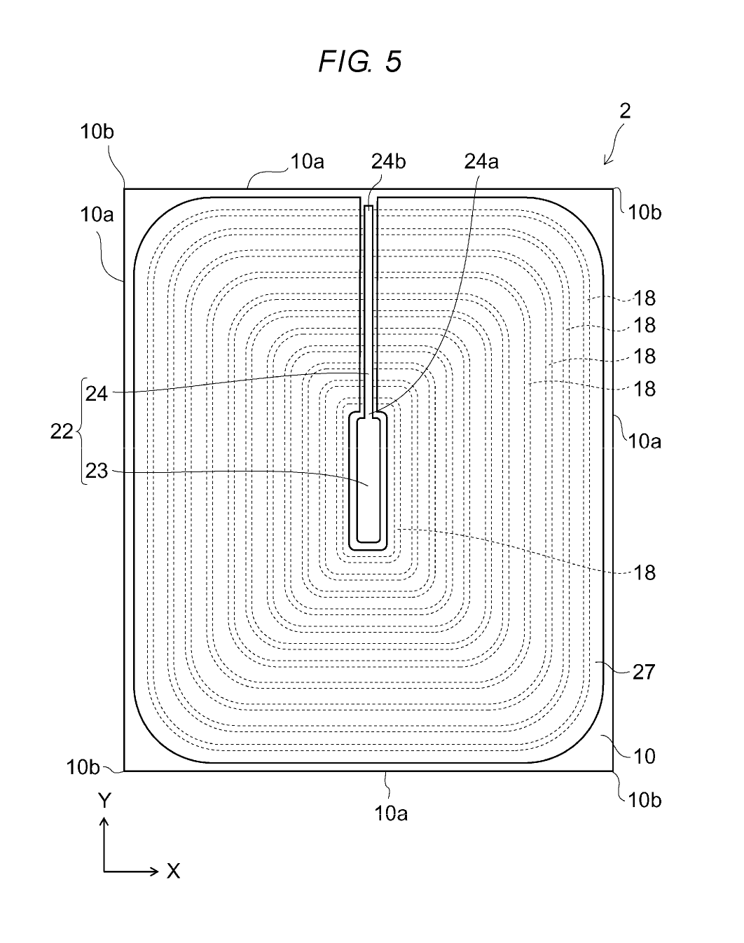

Next, a second embodiment will be described. FIG. 5 is a plan view showing a semiconductor device according to the embodiment.

As shown in FIG. 5, in a semiconductor device 2 according to the embodiment, no wiring portion 25 (see FIG. 1) is provided on the gate wiring 22. Thus, each trench gate electrodes 18 is connected to only the wiring portion 24, and therefore, connected to the gate wiring 22 at one place. The source electrode 27 is arranged in a region where the wiring portion 25 is arranged in the semiconductor device 1 (see FIG. 1) according to the first embodiment.

According to the embodiment, no wiring portion 25 is provided, thus, it is possible to further reduce the area of the gate wiring 22, and correspondingly, increase the area of the source electrode 27, and further reduce the on-resistance. Other configurations, operations and effects of the embodiment are the same as those of the first embodiment described above.

### Third Embodiment

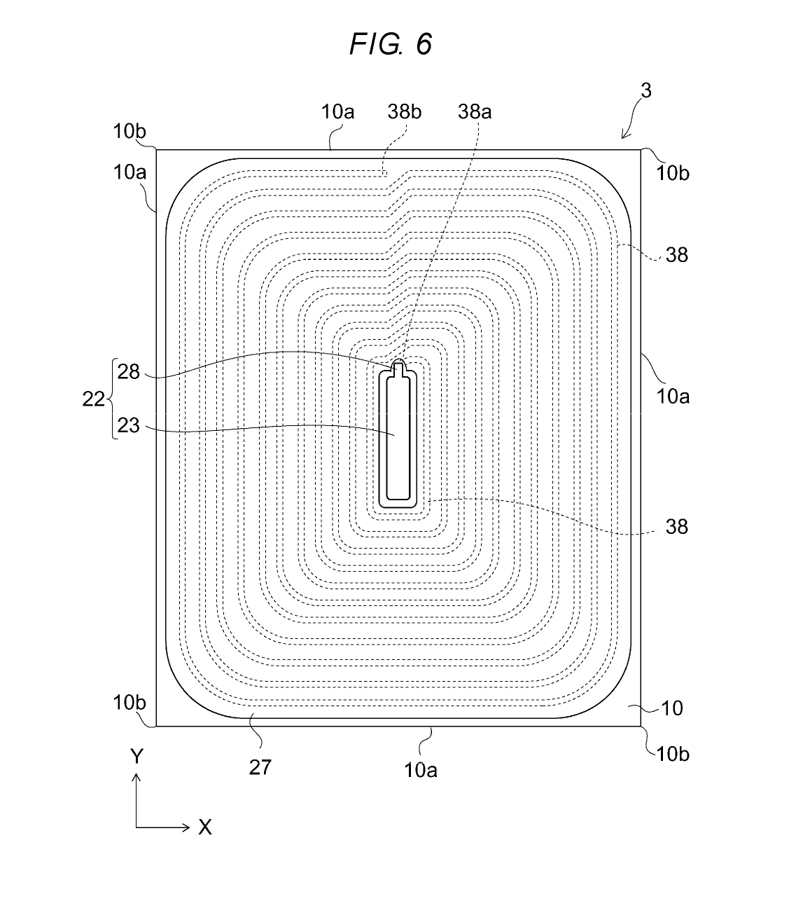

Next, a third embodiment will be described. FIG. 6 is a plan view showing a semiconductor device according to the embodiment.

As shown in FIG. 6, as compared to the semiconductor device 1 (see FIG. 1) according to the first embodiment described above, in a semiconductor device 3 according to the embodiment, no wiring portions 24 and 25 are provided on the gate wiring 22, and a short protruding portion 28 extends from the pad portion 23 in the Y-direction.

Further, in the semiconductor device 3, instead of a plurality of loop-shaped trench gate electrodes 18 in the semiconductor device 1 (see FIG. 1), one spiral trench gate electrode 38 is provided. An end portion 38a on the inner peripheral side of the trench gate electrode 38 is connected to the protruding portion 28 of the gate wiring 22, and an end portion 38b on the outer peripheral side is terminated in the vicinity of the edge 10a of the silicon chip 10.

According to the embodiment, since no wiring portions 24 and 25 are provided on the gate wiring 22, it is possible to further reduce the area of the gate wiring 22 as compared to the first and second embodiments described above. As a result, it is possible to further increase the area of the source electrode 27, and further reduce the on-resistance. Other configurations, operations and effects of the embodiment are the same as those of the first embodiment described above. Note that the protruding portion 28 may extend from the pad portion 23 in the X-direction. Moreover, the end portion on the inner peripheral side of the trench gate electrode 38 may be connected to the pad portion 23 without the protruding portion 28.

According to the embodiment described above, it is possible to achieve a semiconductor device having a low on-resistance.

Note that, although in each embodiment described above, an example in which a semiconductor device is a vertical type MOSFET is presented, without the present disclosure being limited thereto, a vertical type DTMOS or IGBT may be used, for example. In addition, the application of the semiconductor device according to the present disclosure is not limited to power control; the present disclosure may be suitably applied to an application where a low on-resistance is required.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

What is claimed is:

1. A semiconductor device comprising:
a first electrode;
a first semiconductor layer of a first conductivity type located on the first electrode;
a second semiconductor layer of a second conductivity type located on the first semiconductor layer;
a third semiconductor layer of the first conductivity type located on a portion of the second semiconductor layer;
a second electrode located in the first semiconductor layer, the second semiconductor layer and the third semiconductor layer, the second electrode extending along and around an outer edge of the first semiconductor layer, and spaced from the second semiconductor layer by an insulating film;
a wiring located on the third semiconductor layer and connected to the second electrode; and
a third electrode connected to the second semiconductor layer and the third semiconductor layer.

2. The semiconductor device according to claim 1, wherein the second electrode is connected to the wiring at one or two places.

3. The semiconductor device according to claim 1, wherein more than one second electrode is located along the outer edge.

4. The semiconductor device according to claim 3, wherein the wiring includes
a pad portion; and
a wiring portion, a first end portion of which is connected to the pad portion, and a second end portion of which is connected to the outermost second electrode.

5. The semiconductor device according to claim 1, wherein a maximum curvature of the second electrode is smaller than a maximum curvature of the outer edge of the first semiconductor layer.

6. The semiconductor device according to claim 1, wherein at the location of the connection of the second electrode and wiring portion, the second electrode extends further from the second semiconductor layer than it does at other locations.

7. The semiconductor device according to claim 1, wherein the second electrode extends from the wiring in a spiral.

8. The semiconductor device of claim 1, wherein the second electrode comprises a plurality of loops concentrically spaced about the wiring.

9. A semiconductor device, comprising:
a first electrode;
a first semiconductor layer of a first conductivity type located on the first electrode;
a second semiconductor layer of a second conductivity type located on the first semiconductor layer;
a third semiconductor layer of the first conductivity type located on a portion of the second semiconductor layer;
a second electrode located in the first semiconductor layer, the second semiconductor layer and the third semiconductor layer, and spaced from the second semiconductor layer by an insulating film;
a wiring located on the third semiconductor layer and connected to the second electrode; and
a third electrode connected to the second semiconductor layer and the third semiconductor layer,
wherein the second electrode extends around the wiring.

10. The semiconductor device according to claim 9, wherein the second electrode is connected to the wiring at one or two places.

11. The semiconductor device according to claim 9, wherein more than one second electrode extends around the wiring.

12. The semiconductor device according to claim 9, wherein the wiring includes
a pad portion; and
a wiring portion, a first end portion of which is connected to the pad portion, and a second end portion of which is connected to the outermost second electrode.

13. The semiconductor device according to claim 9, wherein a maximum curvature of the second electrode is smaller than a maximum curvature of the outer edge of the first semiconductor layer.

14. The semiconductor device according to claim 9, wherein at the location of the connection of the second electrode and wiring portion, the second electrode extends further from the second semiconductor layer than it does at other locations.

15. The semiconductor device according to claim 9, wherein the second electrode extends from the wiring in a spiral.

16. The semiconductor device of claim 9, wherein the second electrode comprises a plurality of loops concentrically spaced about, and connected to, the wiring.

17. A method of providing a high breakdown voltage and low resistance device, comprising;
providing a first electrode;
providing a first semiconductor layer of a first conductivity type on the first electrode;
providing a second semiconductor layer of a second conductivity type located on the first semiconductor layer;
providing a third semiconductor layer of the first conductivity type located on a portion of the second semiconductor layer;
providing a wiring on the third semiconductor layer;
providing a second electrode, extending around and connected at least one location to the wiring, in the first semiconductor layer, the second semiconductor layer and the third semiconductor layer and, and spacing the second electrode from the second semiconductor layer by an insulating film; and
providing a third electrode connected to the second semiconductor layer and the third semiconductor layer.

18. The method according to claim 17, wherein the second electrode is connected to the wiring at one or at two places.

19. The method according to claim 17, wherein a plurality of second electrodes extend around the wiring.

20. The method according to claim 17, wherein the wiring includes;
a pad portion; and
a wiring portion, a first end portion of which is connected to the pad portion, and a second end portion of which is connected to the outermost second electrode.
